(19) United States
(12) Patent Application Publication
(10) Pub. No.: US 2026/0006895 A1
(43) Pub. Date: Jan. 1, 2026

(54) SEMICONDUCTOR DEVICE AND METHOD OF MANUFACTURING THE SAME

(71) Applicant: FUJI ELECTRIC CO., LTD., Kawasaki-shi (JP)

(72) Inventor: Naoki KUNESHITA, Matsumoto-city (JP)

(73) Assignee: FUJI ELECTRIC CO., LTD., Kawasaki-shi (JP)

(21) Appl. No.: 19/222,298

(22) Filed: May 29, 2025

(30) Foreign Application Priority Data
Jun. 26, 2024 (JP) 2024-102809

(51) Int. Cl. H10D 84/00; H10D 8/00; H10D 8/01; H10D 12/00; H10D 12/01; H10D 62/10; H10D 62/60

(52) U.S. Cl. CPC H10D 84/161; H10D 8/045; H10D 8/422; H10D 12/038; H10D 12/415; H10D 12/481; H10D 62/107; H10D 62/124; H10D 62/60

(57) ABSTRACT

A semiconductor device includes: a drift layer of a first conductivity-type provided in an active area and an edge termination area surrounding the active area; a base region of a second conductivity-type provided on a top surface side of the drift layer in the active area; a main region of the first conductivity-type provided on a top surface side of the base region; and an insulated gate electrode structure provided in contact with the main region and the base region, wherein an effective carrier concentration in the base region is relatively high in a middle part of the active area and is relatively low in a circumferential part of the active area, and a depth of a peak concentration in the base region is deeper than a bottom surface of the main region.

### CROSS-REFERENCE TO RELATED APPLICATION

This application claims benefit of priority under 35 USC 119 based on Japanese Patent Application No. 2024-102809 filed on Jun. 26, 2024, the entire contents of which are incorporated by reference herein.

### BACKGROUND OF THE INVENTION

### 1. Field of the Invention

The present disclosure relates to semiconductor devices and methods of manufacturing the same.

### 2. Description of the Related Art

JP5561922B2 discloses a configuration in which an impurity concentration in a p-type base region is led to be higher in a middle part of a cell region than in an outer circumferential part in order to decrease a current-supply capability in the middle part of the cell region. JPH05-63202A discloses a configuration in which an impurity concentration in a channel-formation region adjacent to a bonding pad is increased so that a threshold voltage is increased.

Siti Rahmah Aid et al., “Formation of shallow p⁺/n junction in silicon using non-melt laser annealing” 11th International Workshop on Junction Technology (IWJT), 2011, p. 132-135 discloses non-melt laser annealing by use of KrF excimer laser or green laser.

S. Blanque et al., “Room Temperature Implantation and Activation Kinetics of Nitrogen and Phosphorus in 4H—SiC Crystals” Materials Science Forum, Vols. 457-460, 2004, p. 893-896 discloses temperature dependency of an activation rate in a case of executing RTA after implanting ions of nitrogen and phosphorus to a silicon carbide substrate.

Seung-Han Yoo et al., “Activation and Deactivation in Heavily Boron-doped Silicon” Journal of the Korean Physical Society, Vol. 43, No. 2, August 2003, p. 290-295 discloses temperature dependency of an activation rate in a case of executing furnace annealing after implanting ions of boron to a silicon substrate.

A gate threshold voltage Vth in an active element is uniform in a plane of an active area of a semiconductor chip, and a current in operation is thus uniform and heat is also generated. The generated heat in the middle part of the active area cannot be released to any regions, and the temperature is thus led to be higher in the middle part of the active area than in the circumferential part, resulting in an increase in loss accordingly.

### SUMMARY OF THE INVENTION

In view of the foregoing problems, the present disclosure provides a semiconductor device and a method of manufacturing the same having a configuration capable of suppressing an increase in temperature in a middle part of an active area so as to decrease a loss.

To solve the problems described above, an aspect of the present disclosure inheres in a semiconductor device including: a drift layer of a first conductivity-type provided in an active area and an edge termination area surrounding the active area; a base region of a second conductivity-type provided on a top surface side of the drift layer in the active area; a main region of the first conductivity-type provided on a top surface side of the base region; and an insulated gate electrode structure provided in contact with the main region and the base region, wherein an effective carrier concentration in the base region is relatively high in a middle part of the active area and is relatively low in a circumferential part of the active area, and a depth of a peak concentration in the base region is deeper than a bottom surface of the main region.

Another aspect of the present disclosure inheres in a method of manufacturing a semiconductor device, including: preparing a drift layer of a first conductivity-type defined in an active area and an edge termination area surrounding the active area; forming a base region of a second conductivity-type on a top surface side of the drift layer in the active area; and forming a main region of the first conductivity-type on a top surface side of the base region, wherein the forming the base region includes implanting impurity ions of the second conductivity-type from the top surface side of the drift layer, and executing laser annealing so as to lead a temperature to be lower in a circumferential part of the active area than in a middle part of the active area.

### BRIEF DESCRIPTION OF THE DRAWINGS

FIG. 1 is a plan view illustrating an example of a semiconductor device according to an embodiment of the present disclosure;

FIG. 2 is a cross-sectional view taken along line A-A′ in FIG. 1;

FIG. 3 is an enlarged cross-sectional view of region C in FIG. 2;

FIG. 4 is a graph showing a profile of an impurity concentration in the semiconductor device according to the embodiment of the present disclosure;

FIG. 5 is a graph showing a profile of an impurity concentration in a semiconductor device of a comparative example;

FIG. 6 is a cross-sectional process view illustrating a method of manufacturing the semiconductor device according to the embodiment of the present disclosure;

FIG. 7 is a cross-sectional process view continued from FIG. 6, illustrating the method of manufacturing the semiconductor device according to the embodiment of the present disclosure;

FIG. 8 is a cross-sectional process view continued from FIG. 7, illustrating the method of manufacturing the semiconductor device according to the embodiment of the present disclosure;

FIG. 9 is a cross-sectional process view continued from FIG. 8, illustrating the method of manufacturing the semiconductor device according to the embodiment of the present disclosure;

FIG. 10 is a cross-sectional process view continued from FIG. 9, illustrating the method of manufacturing the semiconductor device according to the embodiment of the present disclosure;

FIG. 11 is a plan view illustrating a semiconductor wafer in the method of manufacturing the semiconductor device according to the embodiment of the present disclosure;

FIG. 12 is a graph showing temperature dependency of an activation rate of impurity ions;

FIG. 13 is a cross-sectional process view continued from FIG. 10, illustrating the method of manufacturing the semiconductor device according to the embodiment of the present disclosure; and

FIG. 14 is a cross-sectional process view continued from FIG. 13, illustrating the method of manufacturing the semiconductor device according to the embodiment of the present disclosure.

### DETAILED DESCRIPTION

With reference to the drawings, an embodiment of the present disclosure will be described below.

In the drawings, the same or similar elements are indicated by the same or similar reference numerals, and overlapping explanations are not repeated. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The embodiment described below merely illustrates schematically devices and methods for specifying and giving shapes to the technical idea of the present disclosure, and the span of the technical idea is not limited to materials, shapes, structures, and relative positions of elements described herein.

As used in the present specification, an emitter region of an insulated gate bipolar transistor (IGBT) is referred to as “one of the main regions (a first main region)” that can be used as a source region of a metal-oxide-semiconductor field-effect transistor (MOSFET). The “one of the main regions”, when provided in a thyristor such as a MOS controlled static induction thyristor (SI thyristor), can be used as a cathode region. A collector region in the IGBT transistor is referred to as the “other one of the main regions (a second main region)” of the semiconductor device that can be used as a drain region of the MOSFET or as an anode region in the thyristor. The term “main region”, when simply mentioned in the present specification, is referred to as either the first main region or the second main region that is determined as appropriate by the person skilled in the art.

Further, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction. In addition, a “top surface” may be read as “front surface”, and a “bottom surface” may be read as “back surface”.

Further, in the following description, there is exemplified a case where a first conductivity-type is an n-type and a second conductivity-type is a p-type. However, the relationship of the conductivity types may be inverted to set the first conductivity-type to the p-type and the second conductivity-type to the n-type. Further, a semiconductor region denoted by the symbol “n” or “p” attached with “+” indicates that such semiconductor region has a relatively high impurity concentration or a relatively low specific resistance as compared to a semiconductor region denoted by the symbol “n” or “p” without “+”. A semiconductor region denoted by the symbol “n” or “p” attached with “−” indicates that such semiconductor region has a relatively low impurity concentration or a relatively high specific resistance as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration or the same specific resistance.

The term “the same”, “equal”, or “uniform” as used herein does not necessarily strictly have the meaning of “the same”, “equal”, or “uniform”, but may also encompass the meaning of “substantially the same”, “substantially equal”, or “substantially uniform”. Although depending on targets to be used, the term “substantially the same”, “substantially equal”, or “substantially uniform” encompasses a case within a range of +10% of the term of strictly “the same”, “equal”, or “uniform”.

### Embodiment

### <Structure of Semiconductor Device>

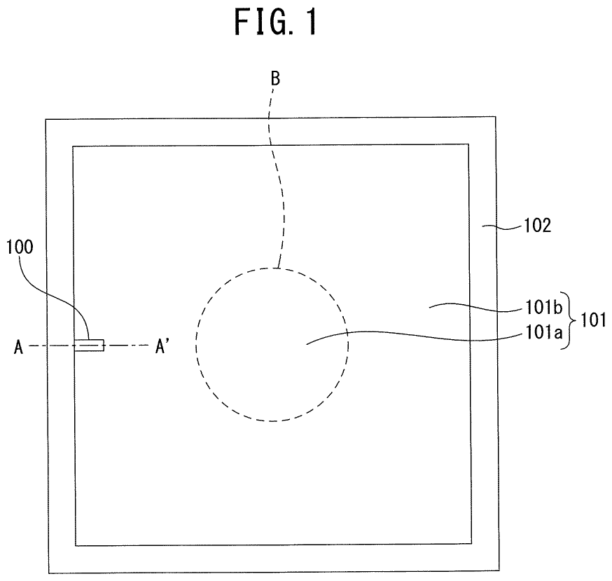

FIG. 1 is a plan view illustrating a semiconductor device (a semiconductor chip) according to an embodiment of the present disclosure as viewed from the top surface (front surface) side. As illustrated in FIG. 1, the semiconductor device according to the embodiment of the present disclosure has a substantially rectangular planar pattern. The semiconductor device according to the embodiment of the present disclosure is implemented by a semiconductor substrate including silicon (Si), for example. The semiconductor device according to the embodiment of the present disclosure may be implemented by a semiconductor substrate including a semiconductor (a wide bandgap semiconductor) having a wider bandgap than Si, such as silicon carbide (SiC), gallium nitride (GaN), gallium oxide (Ga₂O₃), diamond (C), and aluminum nitride (AlN). The case of using the wide bandgap semiconductor for the semiconductor substrate is only required to change temperature conditions for annealing.

The semiconductor device according to the embodiment of the present disclosure includes an active area 101 having a substantially rectangular planar pattern, and an edge termination area (a voltage blocking part) 102 having a loop-shaped (frame-like) planar pattern provided to surround the active area 101. The active area 101 includes a middle part 101a located in the middle (on the inner side) including the middle (the center of gravity) of the planar pattern of the active area 101, and a circumferential part 101b located at the outer circumference (on the outer side) of the planar pattern of the active area 101, as illustrated in FIG. 1. FIG. 1 indicates a virtual circle B by the broken line having a predetermined size, in which the middle part 101a is located on the inside of the circle B, and the circumferential part 101b is located on the outside of the circle B, for example.

The active area 101 includes an active element such as an IGBT and a MOSFET. The circumferential part 101b of the active area 101 is provided with a temperature detection diode (a temperature detector) 100. The temperature detection diode 100 is a p-n junction diode including polysilicon and the like. An anode pad (not illustrated) and a cathode pad (not illustrated) provided in the circumferential part 101b of the active area 101 are electrically connected to the temperature detection diode 100 via wires (not illustrated). The arranged position of the temperature detection diode 100 can be determined as appropriate. The temperature detection diode 101 may be provided in the middle part 101a of the active area 101.

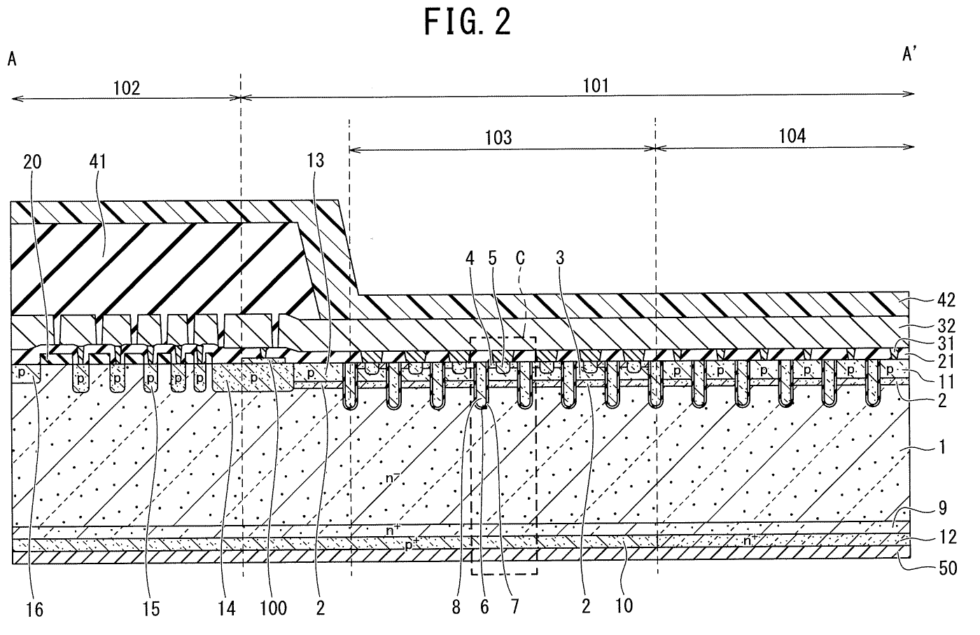

FIG. 2 is a cross-sectional view taken along line A-A′ partly passing through the active area 101 and the voltage blocking part 102 illustrated in FIG. 1. As illustrated in FIG. 2, the active area 101 includes a transistor part 103 including a transistor element and a diode part 104 including a diode element so as to be integrated together in a common semiconductor chip. The semiconductor device according to the embodiment of the present disclosure is a reverse conductive IGBT (RC-IGBT) in which the diode element of the diode part 104 serving as a free-wheeling diode (FWD) is connected in antiparallel to the IGBT that is the transistor element of the transistor part 103. The arranged positions of the transistor part 103 and the diode part 104 in the active area 101 can be changed as appropriate. For example, a plurality of structures similar to the transistor part 103 and the diode part 104 may be arranged alternately in the right-left direction in FIG. 1. The transistor part 103 is included in each of the middle part 101a and the circumferential part 101b of the active area 101.

The semiconductor device according to the embodiment of the present disclosure includes a drift layer 1 of a first conductivity-type (n-type) provided across the active area 101 and the voltage blocking part 102.

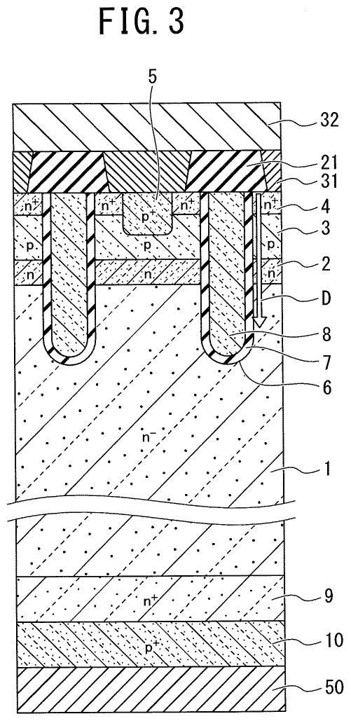

FIG. 3 is an enlarged cross-sectional view of region C partly surrounding the transistor part 103 of the active area 101 illustrated in FIG. 2. As illustrated in FIG. 3, a carrier storage layer (a CS layer) 2 of n-type having a higher impurity concentration than the drift layer 1 is provided on the top surface side of the drift layer 1 in the transistor part 103. The bottom surface of the carrier storage layer 2 is in contact with the top surface of the drift layer 1. The provision of the carrier storage layer 2 can improve the injection enhancement effect (IE effect) of injecting carriers, so as to decrease ON-voltage.

A base region 3 of a second conductivity-type (p-type) is provided on the top surface side of the carrier storage layer 2. The bottom surface of the base region 3 is in contact with the top surface of the carrier storage layer 2. The carrier storage layer 2 is not necessarily provided. The bottom surface of the base region 3 is in contact with the top surface of the drift layer 1 when the carrier storage layer 2 is not provided.

An effective carrier concentration in the base region 3 is highest in the middle part 101a of the active area 101, and gradually decreases toward the outer circumference from the middle part 101a. The effective carrier concentration in the base region 3 is relatively high in the middle part 101a of the active area 101 and is relatively low in the circumferential part 101b of the active area 101. A gate threshold voltage Vth of the IGBT in the transistor part 103 is thus relatively high in the middle part 101a of the active area 101 and is relatively low in the circumferential part 101b of the active area 101. The term “effective carrier concentration” as used in the embodiment of the present disclosure refers to a concentration of carriers in the total ions to be implanted that are activated and positioned between lattices so as to serve as an acceptor or a donor.

An activation rate of the p-type impurity ions implanted to the base region 3 is highest in the middle part 101a of the active area 101, and gradually decreases toward the outer circumference from the middle part 101a. The activation rate of the p-type impurity ions implanted to the base region 3 is relatively high in the middle part 101a of the active area 101 and is relatively low in the circumferential part 101b of the active area 101. The term “activation rate” as used in the embodiment of the present disclosure refers to a ratio of carriers, to the total ions, to be implanted that are activated and positioned between lattices so as to serve as an acceptor or a donor. The activation rate can be obtained as a ratio of a sheet carrier concentration to a dose.

The dose of the p-type impurity ions implanted to the base region 3 is uniform (equal) in the entire plane including the middle part 101a and the circumferential part 101b of the active area 101. The concentration of the total p-type impurity ions including the p-type impurity ions implanted to the base region 3 and activated and the p-type impurity ions implanted to the base region 3 but not activated is thus uniform (equal) in the entire plane including the middle part 101a and the circumferential part 101b of the active area 101.

A depth of the base region 3 is uniform (equal) in the entire plane including the middle part 101a and the circumferential part 101b of the active area 101. The depth of the base region 3 may be deepest in the middle part 101a of the active area 101 and gradually decrease toward the outer circumference from the middle part 101a. The depth of the base region 3 may be relatively deep in the middle part 101a of the active area 101 and relatively shallow in the circumferential part 101b of the active area 101.

As illustrated in FIG. 3, a first main region (an emitter region) 4 of the first conductivity-type (n⁺-type) is provided on the top surface side of the base region 3. The bottom surface of the emitter region 4 is in contact with the top surface of the base region 3. The emitter region 4 has a higher impurity concentration than the drift layer 1 and the carrier storage layer 2.

A position (a depth) of the peak concentration at which the impurity concentration of the p-type impurity ions in the base region 3 is highest is set at a predetermined depth from the top surface of the emitter region 4 and is deeper than the position of the bottom surface of the emitter region 4. The term “position of the bottom surface of the emitter region 4” as used in the embodiment of the present disclosure is defined as a position to which the impurity concentration of the n-type impurity ions in the emitter region 4 gradually decreases in the depth direction so as to have the same concentration as the p-type impurity ions. Namely, the interface of the p-n junction with the base region 3 corresponds to the bottom surface of the emitter region 4.

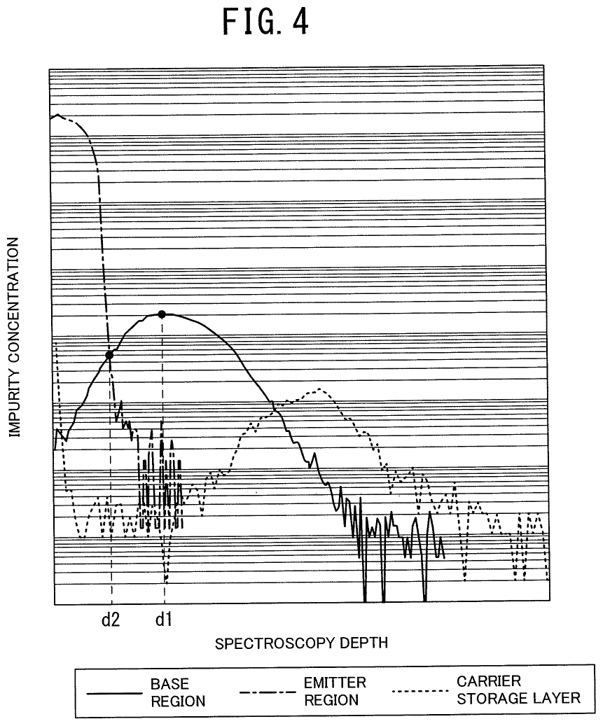

FIG. 4 is a profile of the impurity concentration in each of the emitter region 4, the base region 3, and the carrier storage layer 2 in the depth direction from the top surface of the emitter region 4 indicated by the arrow D shown in FIG. 3 in the semiconductor device according to the embodiment of the present disclosure. This impurity concentration profile is measured by secondary ion mass spectrometry (SIMS). In the semiconductor device according to the embodiment of the present disclosure, the position (the depth) d1 of the peak concentration in the base region 3 is deeper than the position d2 of the bottom surface of the emitter region 4, as shown in FIG. 4. The semiconductor device thus can eliminate the influence of the n-type impurities in the emitter region 4 when an in-plane distribution of a threshold voltage is formed by laser annealing. A manufacturing process for the semiconductor device according to the embodiment of the present disclosure increases acceleration energy upon the ion implantation to about 300 keV or higher and leads the position d1 of the peak concentration to be deeper so as to spread the area of the base region 3 in the depth direction when the p-type impurity ions are implanted for the formation of the base region 3 as described in detail below, instead of the execution of following driving of the entire plane of the active area 101 at a temperature as high as about 1100° C.

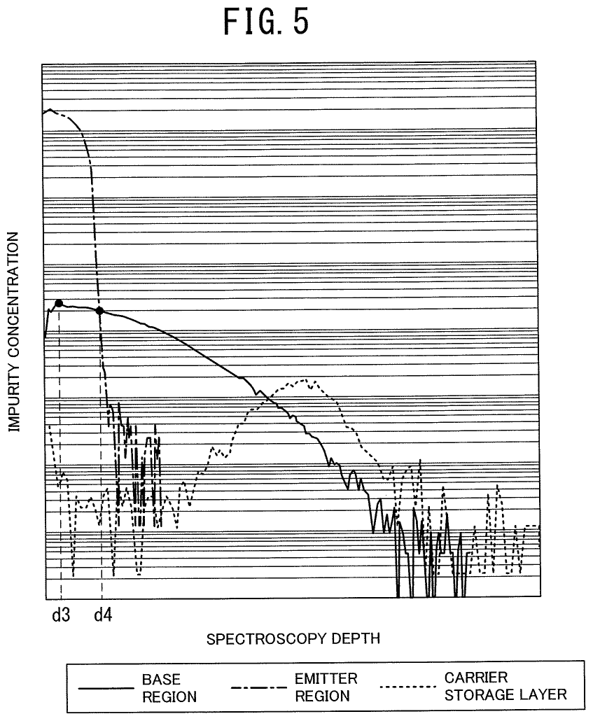

FIG. 5 is a profile of the impurity concentration in each of the emitter region 4, the base region 3, and the carrier storage layer 2 in the depth direction from the top surface of the emitter region 4 indicated by the arrow D shown in FIG. 3 in a semiconductor device of a comparative example. In the semiconductor device of the comparative example, the position (the depth) d3 of the peak concentration in the base region 3 is located around the top surface of the emitter region 4 and is shallower than the position d4 of the bottom surface of the emitter region 4, as shown in FIG. 5. A manufacturing process for the semiconductor device of the comparative example executes the implantation of the p-type impurity ions for forming the base region 3 and then drives the entire plane of the active area 101 at a temperature as high as about 1100° C. so as to lead the p-type impurity ions to be diffused in the depth direction. This process leads the acceleration energy upon the ion implantation to be decreased to about 100 keV and leads the position d3 of the peak concentration to be located around the top surface of the emitter region 4.

As illustrated in FIG. 3, a contact region 5 of the second conductivity-type (p⁺-type) having a higher impurity concentration than the base region 3 is provided on the top surface side of the base region 3 so as to be in contact with the base region 3 and the emitter region 4. While FIG. 3 illustrates the case in which the contact region 5 is in contact with the emitter region 4 in the right-left direction, the contact region 5 and the emitter region 4 may be alternately and repeatedly arranged in the front and back sides of the sheet of FIG. 3.

A plurality of trenches 6 are provided in the depth direction from the top surface of the emitter region 4 separately from each other. The respective trenches 6 penetrate the emitter region 4, the base region 3, and the carrier storage layer 2 to reach the drift layer 1. The side surfaces (the side wall surfaces) of the trenches 6 are in contact with the respective side surfaces of the emitter region 4, the base region 3, and the carrier storage layer 2. The respective trenches 6 may have a straight (stripe-shaped) planar pattern so as to extend parallel to each other in the front and back sides of the sheet of FIG. 3.

A mesa part is provided between the respective trenches 6 arranged next to each other in the parallel direction of the trenches 6 that is the right-left direction in FIG. 3. The mesa part is a region interposed between the respective trenches 6 and located above the deepest position of the trenches 6. The upper part of the drift layer 1, the carrier storage layer 2, the base region 3, the emitter region 4, and the contact region 5 are located in the mesa part.

A gate insulating film 7 is provided to cover the bottom and side surfaces of the respective trenches 6. The gate insulating film 7 as used herein can be a single-layer film of a silicon dioxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂Os) film, or a bismuth oxide (Bi₂O₃) film, or a composite film including some of the above films stacked on one another.

A gate electrode 8 is buried inside the respective trenches 6 with the gate insulating film 7 interposed. The gate electrode 8 as used herein can be made of a polysilicon film (a doped polysilicon film) heavily doped with impurities such as phosphorus (P) or boron (B), for example. The gate insulating film 7 and the gate electrode 8 implement an insulated gate electrode structure (7, 8).

An interlayer insulating film 21 is provided on the top surfaces of the respective insulated gate electrode structures (7, 8). The interlayer insulating film 21 is a single-layer film of a silicon oxide film (a SiO₂ film) without containing phosphorus (P) or boron (B) which is generally referred to as a non-doped silicate glass (NSG) film, a phosphosilicate glass film (a PSG film), a borosilicate glass film (a BSG film), a borophosphosilicate glass film (a BPSG film), a silicon nitride film (a Si₃N₄ film), or a high-temperature oxide film (a HTO film), or a stacked-layer film including some of the above films stacked on one another.

The interlayer insulating film 21 is provided with contact holes on which parts of the respective top surfaces of the emitter region 4 and the contact region 5 are exposed. A contact plug 31 including tungsten (W) is buried in the respective contact holes via a titanium silicide (TiSi₂) film (not illustrated) and a barrier metal film including titanium nitride (TiN) (not illustrated).

A front-surface electrode 32 is provided on the interlayer insulating film 21. The front-surface electrode 32 is electrically connected to the emitter region 4 and the contact region 5 via the contact plugs 31. The front-surface electrode 32 serves as an emitter electrode in the transistor part 103. The front-surface electrode 32 as used herein can include metal such as aluminum (Al), an Al alloy, and copper (Cu). Examples of Al alloys include an Al-silicon (Si) alloy, an Al—Si—Cu alloy, and an Al—Cu alloy.

A field-stop (FS) layer 9 of n-type having a higher impurity concentration than the drift layer 1 is provided on the bottom surface side of the drift layer 1. The top surface of the FS layer 9 is in contact with the bottom surface of the drift layer 1. The provision of the FS layer 9 prevents a depletion layer expanding from the bottom surface side of the base region 3 from reaching a second main region (a collector region) 10 described below. The p⁺-type collector region 10 is provided on the bottom surface side of the FS layer 9. The top surface of the collector region 10 is in contact with the bottom surface of the FS layer 9. The collector region 10 has a higher impurity concentration than the base region 3.

A rear-surface electrode 50 is provided on the bottom surface side of the collector region 10. The rear-surface electrode 50 is, for example, made of a single film including gold (Au), or a metallic film including titanium (Ti), nickel (Ni), and gold (Au) sequentially stacked together. The rear-surface electrode 50 serves as a collector electrode in the transistor part 103.

As illustrated in FIG. 2, the n-type carrier storage layer 2 having a higher impurity concentration than the drift layer 1 is provided on the top surface side of the drift layer 1 in the diode part 104. An anode region 11 of the second conductivity-type (p-type) is provided on the top surface side of the carrier storage layer 2. The bottom surface of the anode region 11 is in contact with the top surface of the carrier storage layer 2. The anode region 11 may be provided to have the same depth and the same impurity concentration as the base region 3 in the transistor part 103.

The plural trenches 6 are dug from the top surface of the anode region 11 in the depth direction in the diode part 104. The trenches 6 in the diode part 104 have the same depth as the trenches 6 provided in the transistor part 103. The respective trenches 6 penetrate the anode region 11 and the carrier storage layer 2 to reach the drift layer 1. The side surfaces of the trenches 6 are in contact with the respective side surfaces of the anode region 11 and the carrier storage layer 2.

The upper part of the drift layer 1, the carrier storage layer 2, and the anode region 11 are located in the mesa part interposed between the respective trenches 6 in the diode part 104. The front-surface electrode 32 is provided on the top surface side of the anode region 11 via the interlayer insulating film 21. The front-surface electrode 32 is provided continuously from the transistor part 103. The front-surface electrode 32 is electrically connected to the anode region 11 via the contact plugs 31 buried in the contact holes provided in the interlayer insulating film 21. The front-surface electrode 32 serves as an anode electrode in the diode part 104. A passivation resist film 42 is provided on the top surface side of the front-surface electrode 32. The passivation resist film 42 is provided to extend across the transistor part 103 and the diode part 104.

A cathode region 12 of n⁺-type having a higher impurity concentration than the FS layer 9 is provided on the bottom surface side of the FS layer 9 in the diode part 104. The top surface of the cathode region 12 is in contact with the bottom surface of the FS layer 9. The cathode region 12 is provided to have the same depth as the collector region 10. The side surface of the cathode region 12 is in contact with the side surface of the collector region 10. The rear-surface electrode 50 serves as a cathode electrode in the diode part 104.

The n-type carrier storage layer 2 and a well region 13 of p-type are provided on the top surface side of the drift layer 1 in a region adjacent to the voltage blocking part 102 on the outside of the transistor part 103 of the active area 101. A well region 14 of p-type having a greater depth than the well region 13 is provided on the outside of the carrier storage layer 2 and the well region 13 so as to be in contact with each other. The temperature detection diode 100 is provided on the top surface side of the well region 14 with an insulating film (not illustrated) interposed. The front-surface electrode 32 is provided on the top surface side of the temperature detection diode 100 with the interlayer insulating film 21 interposed. The front-surface electrode 32 is electrically connected to the temperature detection diode 100 via the contact plugs 31 buried in the contact holes provided in the interlayer insulating film 21. The front-surface electrode 32 serves as a wire, and is electrically connected to the anode pad or the cathode pad (not illustrated).

As illustrated in FIG. 2, a plurality of guard-ring layers 15 are provided separately from each other on the top surface side of the drift layer 1 in the voltage blocking part 102. A channel stopper 16 of p-type is provided on the top surface side of the drift layer 1 at the outer circumferential edge of the voltage blocking part 102. The front-surface electrode 32 is provided on the top surface side of the guard-ring layers 15 and the channel stopper 16 with an insulating film 20 and the interlayer insulating film 21 interposed. The front-surface electrode 32 is electrically connected to the guard-ring layers 15 via the contact plugs 31 buried in the contact holes provided in the interlayer insulating film 21. A passivation film 41 including polyimide and the like is provided on the top surface side of the front-surface electrode 32. The passivation resist film 42 is provided on the top surface side of the passivation film 41.

When the semiconductor device according to the embodiment of the present disclosure during the operation applies a positive voltage to the rear-surface electrode 50 while applying a ground potential to the front-surface electrode 32 in the IGBT of the transistor part 103 and also applies a positive voltage greater than or equal to the gate threshold voltage Vth to the gate electrode 8, an inversion layer (a channel) is formed in the base region 3 toward the side surfaces of the trenches 6 so as to be in the ON-state. In the ON-state, a current flows from the rear-surface electrode 50 toward the front-surface electrode 32 through the collector region 10, the FS layer 9, the drift layer 1, the carrier storage layer 2, the inversion layer of the base region 3, and the emitter region 4.

When the voltage applied to the gate electrode 8 is smaller than the gate threshold voltage Vth, the semiconductor device is led to be in the OFF-state since no inversion layer is formed in the base region 3, while no current flows from the rear-surface electrode 50 toward the front-surface electrode 32. The diode part 104 causes a flow of a reflux current in the opposite direction when the IGBT of the transistor part 103 is turned OFF. A switching loss or a conduction loss upon the ON or OFF operation of the IGBT generates heat.

Regarding conventional semiconductor devices, an active element such as an IGBT is managed so that a variation in manufacture is reduced in a wafer plane, in a rod, between batches, or the like. Such semiconductor devices are manufactured so that the gate threshold voltage Vth has good uniformity through strict management regarding various items such as a film thickness of a gate insulating film. At the same time, a cell density tends to increase and a current density also increases in association with promotion of micronization of IGBTs and the like. This easily causes an increase in temperature of chips and impedes a normal operation of the chips if exceeding a maximum junction temperature Tjₘₐₓ because of heat generation, which may shorten the life time or could cause damage.

A protection for chips against the temperature increase is required in order to ensure a normal operation or prevention against damage. A temperature detection diode is thus arranged around the middle of a chip for protection so as to activate a heat protection function and stop the operation when exceeding the maximum junction temperature Tjₘₐₓ to avoid damage to the chip. Such a protection for the chip enables restarting if the temperature decreases, and the operation is thus guaranteed. However, the arrangement of the temperature detection diode around the middle of the chip inevitably decreases the active area while increasing the chip size.

In contrast, the semiconductor device according to the embodiment of the present disclosure has the configuration in which the effective carrier concentration in the base region 3 is led to have a gradient so as to be uneven in the plane of the active area 101, that is, relatively high in the middle part 101a of the active area 101 and relatively low in the circumferential part 101b of the active area 101. This also leads the gate threshold voltage Vth of the IGBT in the transistor part 103 to have a gradient so as to be uneven in the plane of the active area 101, that is, relatively high in the middle part 101a of the active area 101 and relatively low in the circumferential part 101b of the active area 101.

The timing when the IGBT is turned ON is thus led to be nonuniform in the plane of the active area 101, namely, the IGBT in the circumferential part 101b of the active area 101 is turned ON first, and the IGBT in the middle part 101a of the active area 101 is then turned ON with a time lag. This shortens the time during which the current flows more in the IGBT in the middle part 101a of the active area 101 than in the IGBT in the circumferential part 101b, so as to avoid the temperature increase in the middle part 101a of the active area 101 and reduce a loss accordingly.

The avoidance of the temperature increase in the IGBT in the middle part 101a of the active area 101 can also ensure uniformity of the temperature increase in the entire plane of the active area 101. This eliminates the necessity of placing the temperature detection diode 100 in the middle part 101a of the active area 101, while allowing the arrangement in the circumferential part 101b or at the outer circumference instead of the middle part 101a. Such an arrangement can increase the area of the active area 101 and reduce the size of the chip.

This configuration can also expand the allowance (margin) of the maximum junction temperature Tjₘₐₓ, which is conventionally fixed in the middle of the chip, so as to extend a safe operating area (SOA) provided against the temperature increase. The semiconductor device according to this embodiment thus can reduce a rate of malfunction, so as to improve the reliability.

### <Method of Manufacturing Semiconductor Device>

An example of the method of manufacturing the semiconductor device according to the embodiment of the present disclosure is described below. The method of manufacturing the semiconductor device described below is one of examples, and it should be understood that the semiconductor device according to this embodiment can be achieved by various manufacturing methods including modified examples within the scope of the appended claims.

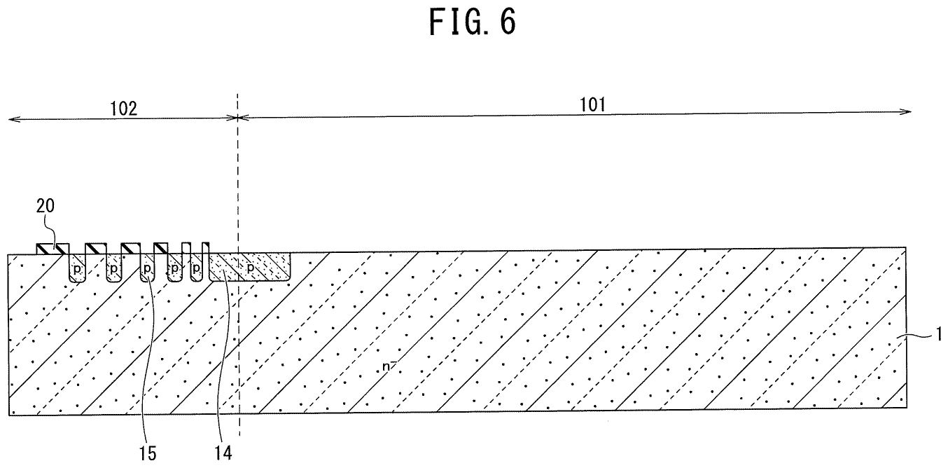

First, a semiconductor substrate (a semiconductor wafer) of the first conductivity-type (n⁻-type) including silicon (Si) is prepared so as to serve as the drift layer 1 (refer to FIG. 6). While the following explanations are made with reference to the cross section corresponding to the semiconductor chip illustrated in FIG. 2, a plurality of chip regions implementing a plurality of semiconductor chips each common to the semiconductor chip illustrated in FIG. 2 are formed in the semiconductor wafer.

The drift layer 1 is defined in each of the active area 101 and the voltage blocking part 102. Next, the insulating film 20 (refer to FIG. 6) is formed on the top surface of the drift layer 1, and delineated by photolithography and dry etching. Using the delineated insulating film 20 as a mask for ion implantation, p-type impurity ions such as boron (B) are implanted so as to form the p-type well region 14 and the p-type guard-ring layers 15 (refer to FIG. 6). The p-type well region 14 and the p-type guard-ring layers 15 are then formed by annealing, as illustrated in FIG. 6. The insulating film 20 used as the mask for ion implantation partly located in the active area 101 is removed so as to lead the insulating film 20 located in the voltage blocking part 102 to partly remain.

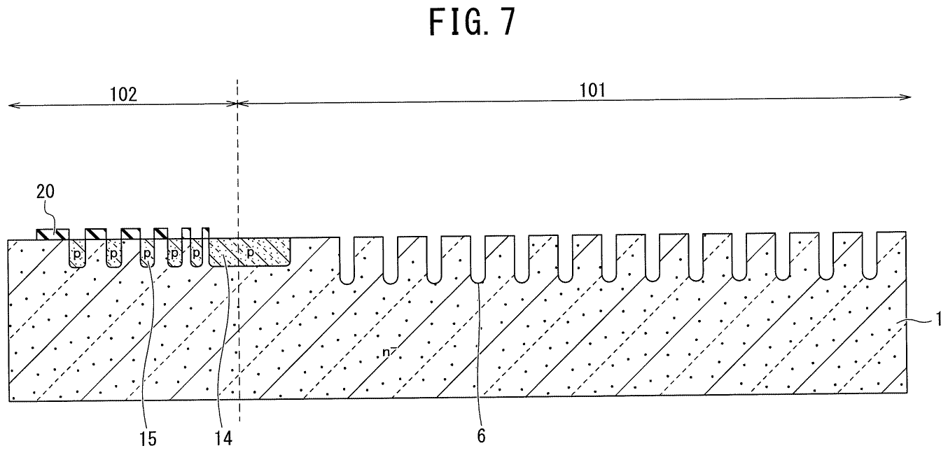

Next, the upper part of the drift layer 1 in the active area 101 is selectively removed by photolithography and dry etching. This step provides the plural trenches 6 at the upper part of the drift layer 1 in the active area 101, as illustrated in FIG. 7.

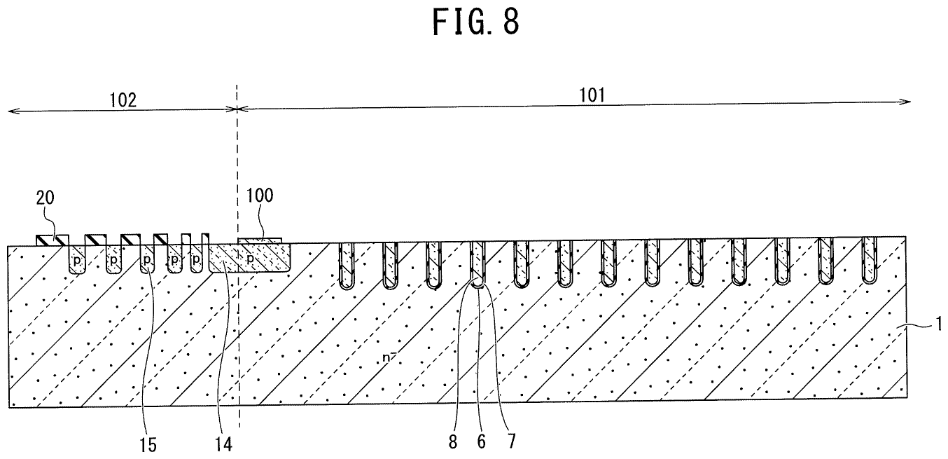

Next, the gate insulating film 7 (refer to FIG. 8) is formed on the bottom and side surfaces of the respective trenches 6 by a thermal oxidation method or a chemical vapor deposition (CVD) method, for example. Next, a polysilicon film (a doped polysilicon film) heavily doped with impurity ions such as phosphorus (P) and boron (B) is deposited by the CVD method or the like to fill the inside of the respective trenches 6 with the gate insulating film 7 interposed. The polysilicon film and the gate insulating film 7 are then selectively removed by photolithography and dry etching. This step forms the gate insulating film 7 and the gate electrode 8 made of the polysilicon film are formed inside the respective trenches 6 so as to implement the insulated gate electrode structure (7, 8), as illustrated in FIG. 8. In addition, the temperature detection diode 100 made of the polysilicon film is formed on the top surface side of the well region 14 with an insulating film (not illustrated) interposed at the outer circumference of the active area 101.

Next, a photoresist film is applied to the top surface of the drift layer 1, and is delineated by photolithography. Using the delineated photoresist film as a mask for ion implantation, p-type impurity ions such as boron (B) are implanted from the top surface side of the drift layer 1 so as to form the p-type base region 3 in the transistor part 103, the p-type anode region 11 in the diode part 104, and the like. The ion implantation may be executed either at a single step or at multiple steps using different levels of acceleration energy. The acceleration energy during the ion implantation is uniform (equal) in the entire plane of the active area 101. The acceleration energy during the ion implantation is adjusted so that the position (the depth) of the peak concentration of the p-type impurity ions in the base region 3 is deeper than the bottom surface of the emitter region 4. The acceleration energy during the ion implantation is in a range of about 300 keV or higher and 650 keV or lower, for example. The dose upon the ion implantation is uniform (equal) in the entire plane of the active area 101, and is in a range of about 1×10¹³ ions/cm² or greater and 1×10¹⁵ ions/cm² or smaller, for example. The photoresist film is then removed.

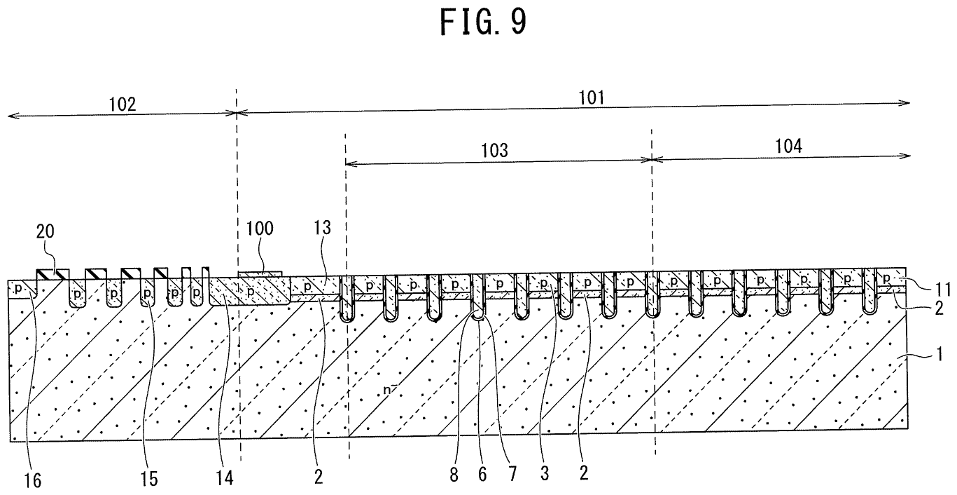

Next, a photoresist film is applied to the top surface of the drift layer 1, and is delineated by photolithography. Using the delineated photoresist film as a mask for ion implantation, n-type impurity ions such as phosphorus (P) and arsenic (As) are implanted from the top surface side of the drift layer 1 so as to form the n-type carrier storage layer 2. The photoresist film is then removed. The structure at this point is as illustrated in FIG. 9.

Next, a photoresist film is applied to the top surface of the drift layer 1, and is delineated by photolithography. Using the delineated photoresist film as a mask for ion implantation, p-type impurity ions such as boron (B) are implanted from the top surface side of the drift layer 1 so as to form the p⁺-type contact region 5 in the transistor part 103. The photoresist film is then removed.

Next, a photoresist film is applied to the top surface of the drift layer 1, and is delineated by photolithography. Using the delineated photoresist film as a mask for ion implantation, n-type impurity ions such as phosphorus (P) and arsenic (As) are implanted from the top surface side of the drift layer 1 so as to form the n⁺-type emitter region 4 in the transistor part 103. The photoresist film is then removed.

The order of the ion implantation for forming the base region 3 and the anode region 11, the ion implantation for forming the carrier storage layer 2, the ion implantation for forming the contact region 5, and the ion implantation for forming the emitter region 4 is not limited to the case described above and can be changed as appropriate.

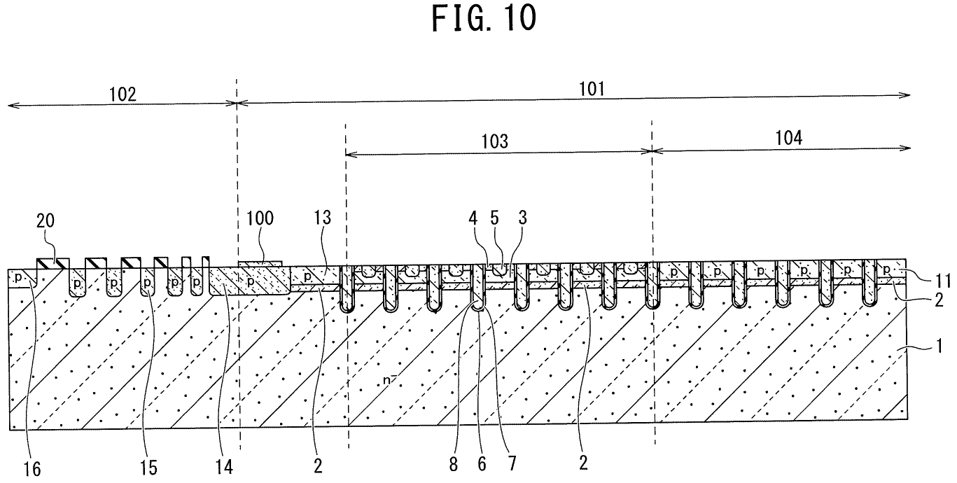

Next, the p-type impurity ions and the n-type impurity ions, which are dopants implanted to the drift layer 1 so as to form the base region 3 and the anode region 11, form the carrier storage layer 2, form the contact region 5, and form the emitter region 4, are activated by annealing (activation annealing). This step forms the n-type carrier storage layer 2, the p-type base region 3, the n⁺-type emitter region 4, and the p⁺-type contact region 5 on the top surface side of the drift layer 1 in the transistor part 103, and also forms the n-type carrier storage layer 2 and the p-type anode region 11 on the top surface side of the drift layer 1 in the diode part 104, as illustrated in FIG. 10. Further, this step forms the p-type well region 13 on the outer circumferential side in the active area 101, and forms the p-type channel stopper 16 in the voltage blocking part 102.

This annealing (the activation annealing) includes annealing (first annealing) executed so as to increase the temperature more in the middle part 101a than in the circumferential part 101b in the active area 101. For example, the annealing is executed so that the middle part 101a of the active area 101 is heated at a temperature in a range of about 1000° C. or higher and 1100° C. or lower, while the circumferential part 101b of the active area 101 is heated at a temperature, which is lower than the temperature for heating the middle part 101a of the active area 101, in a range of about 900° C. or higher and 1000° C. or lower, for example. The activation rate of the p-type impurity ions implanted to the base region 3, which depends on the annealing temperature, is relatively high in the middle part 101a of the active area 101 and relatively low in the circumferential part 101b of the active area 101. The effective carrier concentration in the base region 3 is thus relatively high in the middle part 101a of the active area 101 and relatively low in the circumferential part 101b of the active area 101.

The annealing executed so as to have the temperature gradient in the plane of the active area 101 is laser annealing by use of a step-and-repeat type laser annealing device, for example. In particular, the middle part 101a of the active area 101 is locally irradiated with a laser beam from the top surface side of the drift layer 1 so that the temperature is led to be highest in the middle part 101a and gradually decreases toward the outer circumference from the middle part 101a.

The laser beam used for the laser annealing can be either excimer laser (with a wavelength of 248 nanometers) such as krypton fluoride (KrF) or green laser (with a wavelength of 532 nanometers), for example. The laser beam when using KrF has laser power in a range of about 250 mJ/cm² or higher and 500 mJ/cm² or lower, and has pulse duration (full width of half maximum) in a range of 30 ns or greater and 40 ns or less, for example. The laser beam when using green laser has laser power in a range of about 655 mJ/cm² or higher and 800 mJ/cm² or lower, and has pulse duration (full width of half maximum) in a range of 100 ns or greater and 120 ns or less, for example.

A spot diameter of the laser beam is smaller than the area of the active area 101, which is in a range of about one quarter or greater and one half or smaller of the area of the active area 101, for example. A shape of the laser beam may be either a circle or a square. A heating temperature of the laser beam is in a range of about 1000° C. or higher and 1100° C. or lower, for example. When the semiconductor substrate includes silicon, the execution of non-fusion annealing at a temperature lower than a fusing temperature of silicon (1420° C.) can keep flatness of the top surface of the semiconductor substrate. Alternatively, fusion annealing at a temperature higher than or equal to the fusing temperature of silicon may be executed, and flattening processing may be then executed.

The positions in the X direction and the Y direction and the rotation θ are adjusted by course alignment for positioning the semiconductor wafer, for example. If the accuracy is required, fine alignment is then executed in which gaps at several points are measures by sampling measurement in the wafer plane, statistical processing is executed, and the rotation or magnification of the wafer is corrected. The stage position or the light source is then moved by step-and-repeat processing, and the ON-OFF (in some cases, strength and weakness) operations upon the laser irradiation are repeated for each chip region so as to execute the annealing in all of the chip regions. The laser beam is turned ON in the middle part of the respective chip regions, and may be irradiated locally while being fixed (stopped) at one position when the chip region is small. Alternatively, when the chip region is large, the spot diameter may be adjusted so as to be increased, the laser beam may be irradiated to plural positions of the middle part of the chip region, or may be scanned crosswise in the middle part of the chip region. The irradiation with the laser beam in the middle part of the chip region gradually decreases the heating temperature from the middle part of the chip region toward the chip end part.

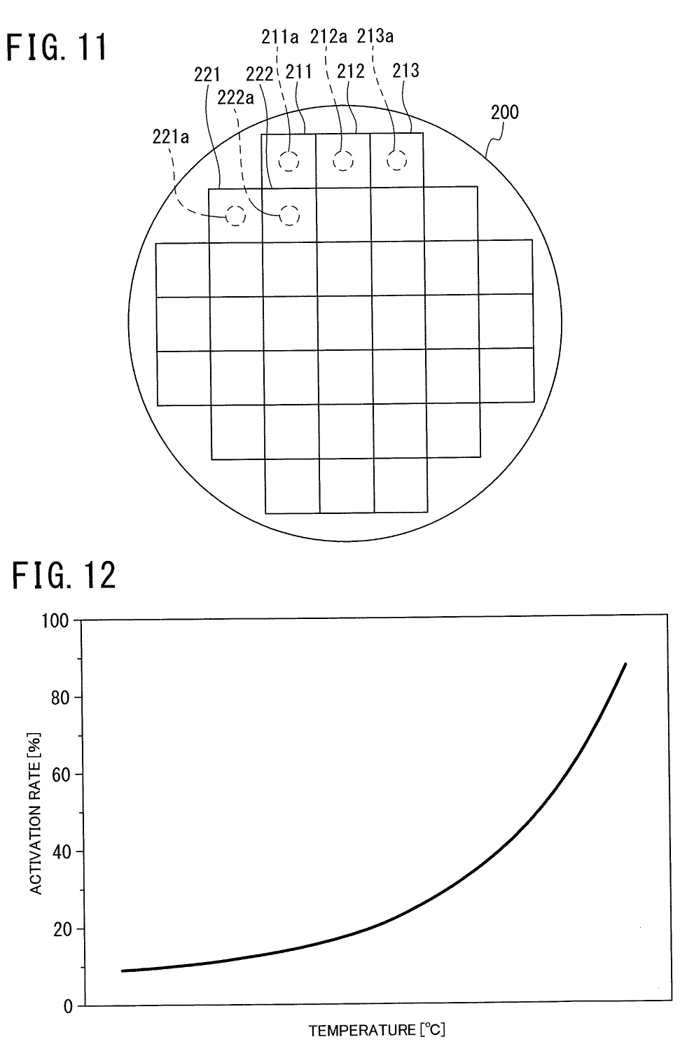

FIG. 11 is a schematic plan view illustrating a semiconductor wafer 200. The semiconductor wafer 200 is provided with a plurality of chip regions 211, 212, 213, 221, 222, and the like. The laser annealing step locally and independently irradiates, with the laser beam, the positions fixed to the middle parts 211a, 212a, 213a, 221a, 222a, . . . of the chip regions 211, 212, 213, 221, 222, . . . by the step-and-repeat processing, for example.

The laser annealing may be executed by scanning, instead of the step-and-repeat processing. For example, as illustrated in FIG. 11, when the chip regions 211, 212, and 213 in the semiconductor wafer 200 are sequentially and continuously scanned, the power for the scanning may be relatively decreased in the circumferential parts other than the middle parts 211a, 212a, and 213a of the chip regions 211, 212, and 213, while the power may be relatively increased in the middle parts 211a, 212a, and 213a of the chip regions 211, 212, and 213. Alternatively, the scanning speed may be relatively increased in the circumferential parts of the chip regions 211, 212, and 213, while the scanning speed may be relatively decreased in the middle parts 211a, 212a, and 213a of the chip regions 211, 212, and 213 so as to adjust the activation rate.

FIG. 12 is a graph showing temperature dependency of the activation rate of the ions. As shown in FIG. 12, the activation rate of the ions tends to be higher as the temperature during the annealing is higher. While FIG. 12 illustrates an example of the temperature dependency of the activation rate of the ions when nitrogen (N) and the phosphorus (P) are implanted to silicon carbide (SiC), a similar tendency can be obtained in a case in which p-type impurity ions such as boron (B) are implanted to silicon (Si).

In addition, a step of entire annealing (second annealing) for evenly heating the entire plane of the active area 101 is executed either before or after the local laser annealing step. The entire annealing evenly heats the entire plane of the semiconductor wafer and also the entire plane of the respective chip regions by annealing by use of a batch annealing apparatus or by rapid thermal annealing (RTA) by use of a sheet-fed annealing apparatus. A heating temperature during the entire annealing is lower than the heating temperature during the laser annealing, which is in a range of about 900° C. or higher and 1000° C. or lower, for example. The entire annealing is not necessarily executed if the activation by the laser annealing is sufficiently exhibited for the intended area including the circumferential part 101b of the active area 101.

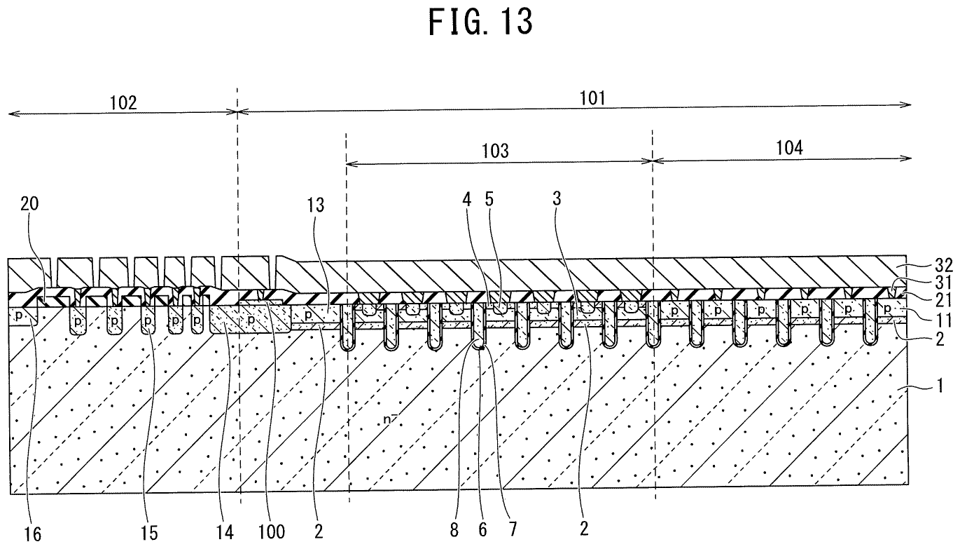

Next, the interlayer insulating film 21 (refer to FIG. 13) is formed on the top surface of the active area 101 and the voltage blocking part 102 by a CVD method. Next, the contact holes are open in the interlayer insulating film 21 by photolithography and dry etching. Next, the contact plugs 31 (refer to FIG. 13) are buried in the contact holes via a barrier metal film (not illustrated) by sputtering or vapor deposition, dry etching, and the like.

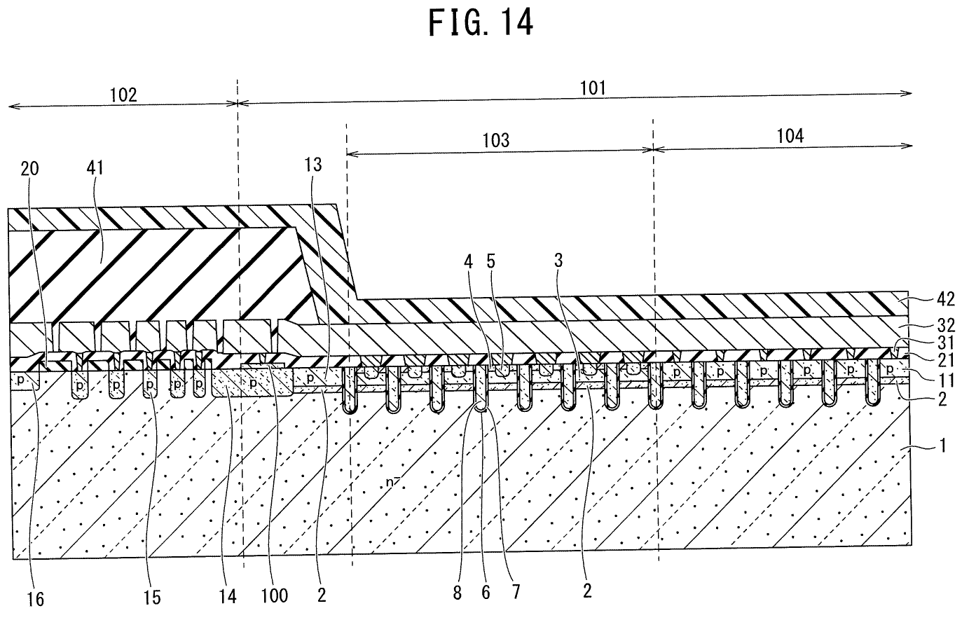

Next, the front-surface electrode 32 (refer to FIG. 13) is deposited on the top surfaces of the contact plugs 31 and the interlayer insulating film 21 by sputtering, vapor deposition, or the like. The front-surface electrode 32 is then partly and selectively removed by photolithography and dry etching, as illustrated in FIG. 13. Next, the passivation film 41 (refer to FIG. 14) is formed so as to cover the front-surface electrode 32 in the voltage blocking part 102. Next, as illustrated in FIG. 14, the passivation resist film 42 is formed so as to cover the front-surface electrode 32 in the active area 101 and the passivation film 41 in the voltage blocking part 102.

Next, the drift layer 1 is ground from the bottom surface side by backside grinding (BG) or the like so that the thickness of the drift layer 1 is adjusted to have an intended thickness of a product. Next, the n-type FS layer 9 is formed on the bottom surface side of the drift layer 1 illustrated in FIG. 2 by photolithography and ion implantation. Further, p⁺-type collector region 10 is formed on the bottom surface side of the FS layer 9 in the transistor part 103 illustrated in FIG. 2 and the n⁺-type cathode region 12 is formed on the bottom surface side of the FS layer 9 in the diode part 104 by photolithography and ion implantation.

Next, the rear-surface electrode 50 including gold (Au) is formed on the bottom surface of the collector region 10 and the cathode region 12 illustrated in FIG. 2 by sputtering, vapor deposition, or the like. Thereafter, the semiconductor substrate provided with the plural chip regions is cut (diced) into individual pieces, so as to complete the semiconductor device according to the embodiment of the present disclosure.

The method of manufacturing the semiconductor device according to the embodiment of the present disclosure executes the activation annealing so as to increase the temperature more in the middle part 101a than in the circumferential part 101b of the active area 101 after the implantation of the p-type impurity ions for forming the base region 3, so as to increase the activation rate of the ions more in the middle part 101a of the active area 101 than in the circumferential part 101b of the active area 101. This can avoid an increase in temperature in the middle part 101a of the active area 101 caused in association with the operation of the IGBT to decrease a loss accordingly.

Further, the method of manufacturing the semiconductor device according to the embodiment of the present disclosure executes the ion implantation for forming the base region 3 with the uniform dose on the entire plane of the active area 101, and then leads the activation rate of the ions to be uneven and leads the effective carrier concentration to be uneven in the plane of the active area 101 by laser annealing. This can eliminate the photolithography step and the ion implantation step, so as to reduce the cost and the lead time, as compared with a case of leading the impurity concentration to be uneven by repeating the ion implantation several times with different doses. Further, this method only needs to adjust the conditions for the laser annealing, so as to easily change the in-plane distribution of the effective carrier concentration of the base region 3 in the active area 101.

### OTHER EMBODIMENTS

As described above, the invention has been described according to the embodiment, but it should not be understood that the description and drawings implementing a portion of this disclosure limit the invention. Various alternative embodiments of the present disclosure, examples, and operational techniques will be apparent to those skilled in the art from this disclosure.

While the semiconductor device according to the embodiment of the present disclosure is illustrated above with the RC-IGBT as the active element of the active area 101, the present disclosure can also be applied to other IGBTs instead the RC-IGBT. For example, the present disclosure may be applied to a reverse-blocking insulated gate bipolar transistor (RB-IGBT) or a simple IGBT. The embodiment of the present disclosure may also be applied to a MOSFET, as the active element of the active area 101 of the semiconductor device, having a configuration including an n⁺-type drain region substituted for the p⁺-type collector region 10 of the IGBT in the transistor part 103 illustrated in FIG. 2 and FIG. 3. In addition, while the semiconductor device according to the embodiment of the present disclosure is illustrated above with the trench-gate active element used for the active area 101, the present disclosure may also be applied to a case of using a planer-gate active element.

In addition, the respective configurations disclosed in the embodiment can be combined together as appropriate without contradiction with each other. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising
a drift layer of a first conductivity-type provided in an active area and an edge termination area surrounding the active area;
a base region of a second conductivity-type provided on a top surface side of the drift layer in the active area;
a main region of the first conductivity-type provided on a top surface side of the base region; and
an insulated gate electrode structure provided in contact with the main region and the base region,
wherein an effective carrier concentration in the base region is relatively high in a middle part of the active area and is relatively low in a circumferential part of the active area, and
a depth of a peak concentration in the base region is deeper than a bottom surface of the main region.

2. The semiconductor device of claim 1, wherein a total concentration of activated impurities and inactivated impurities in the base region is uniform in an entire plane of the active area.

3. The semiconductor device of claim 1, wherein a depth of the base region is uniform in an entire plane of the active area.

4. The semiconductor device of claim 1, wherein an activation rate of impurity ions in the base region is relatively high in the middle part of the active area and is relatively low in the circumferential part of the active area.

5. A method of manufacturing a semiconductor device, comprising:
preparing a drift layer of a first conductivity-type defined in an active area and an edge termination area surrounding the active area;
forming a base region of a second conductivity-type on a top surface side of the drift layer in the active area; and
forming a main region of the first conductivity-type on a top surface side of the base region,
wherein the forming the base region includes
implanting impurity ions of the second conductivity-type from the top surface side of the drift layer, and
executing laser annealing so as to lead a temperature to be lower in a circumferential part of the active area than in a middle part of the active area.

6. The method of manufacturing the semiconductor device of claim 5, wherein the implanting the impurity ions of the second conductivity-type is executed so that a depth of a peak concentration of the impurities of the second conductivity-type is deeper than a bottom surface of the main region.

7. The method of manufacturing the semiconductor device of claim 5, wherein the executing the laser annealing locally and independently irradiates middle parts of a plurality of chip regions provided in a semiconductor wafer with a laser beam.

8. The method of manufacturing the semiconductor device of claim 5, wherein the forming the base region further includes subjecting to annealing an entire plane of the active area uniformly at a temperature lower than a temperature during the laser annealing.

9. The method of manufacturing the semiconductor device of claim 5, further comprising forming a guard-ring layer of the second conductivity-type on the top surface side of the drift layer in the edge termination area before the forming the base region.

10. The method of manufacturing the semiconductor device of claim 5, further comprising forming a contact plug in contact with the main region after the forming the base region.
